(19) United States
(12) Patent Application Publication
(10) Pub. No.: US 2026/0107582 A1
(43) Pub. Date: Apr. 16, 2026

(54) SOLAR CELL MODULE

(71) Applicant: TOYOTA JIDOSHA KABUSHIKI KAISHA, Toyota-shi (JP)

(72) Inventors: Shoichi IWAMOTO, Fuji-shi (JP); Ryuzo Tagami, Toyota-shi (JP); Ryota Morikawa, Osaka-shi (JP); Yuya Okuda, Nisshin-shi (JP); Shinya Iwasaki, Mizuho-shi (JP); Shintaro Hinata, Toyota-shi (JP); Hiroki Ushio, Toyota-shi (JP)

(73) Assignee: TOYOTA JIDOSHA KABUSHIKI KAISHA, Toyota-shi (JP)

(21) Appl. No.: 19/325,082

(22) Filed: Sep. 10, 2025

(30) Foreign Application Priority Data
Oct. 11, 2024 (JP) 2024-179349

(51) Int. Cl. H10F 19/85; H10F 19/90

(52) U.S. Cl. CPC H10F 19/85; H10F 19/904

(57) ABSTRACT

Provided is a solar cell module with high rigidity capable of reducing the manufacturing cost. The solar cell module includes a front surface plate and a back surface plate that are disposed, via a sealing material, on a light-receiving surface side and an opposite side of the light-receiving surface side of the solar cell unit, in which a woven metal plate is provided on the back surface plate, the woven metal plate being formed by weaving metal strips having a predetermined strip width.

### CROSS REFERENCE TO RELATED APPLICATIONS

The present application claims priority from Japanese patent application JP 2024-179349 filed on Oct. 11, 2024, the entire content of which is hereby incorporated by reference into this application.

### BACKGROUND

### Technical Field

The present disclosure relates to a solar cell module.

### Background Art

JP 2013-004835 A discloses a solar cell module in which metal foil, a metal mesh, or the like is provided on a back surface plate on a side opposite to a light incident side. This solar cell module is a flexible solar cell module including a solar cell and resin films laminated on a light-receiving surface side and a non-light-receiving surface side of the solar cell via sealing materials, the solar cell module further including a fire spread prevention sheet joined via the resin film to the non-light-receiving surface side of the solar cell, in which the fire spread prevention sheet is formed of a flexible sheet containing any of metal foil, a metal mesh, and inorganic fiber cloth. It is stated that because of the foregoing, burning of the module surface can be prevented from spreading to a backside (building side), and a temperature increase in the module itself is also suppressed, thereby improving the flame resistance as a module.

### SUMMARY

When mounted on a bonnet hood, for example, an on-vehicle solar cell module with a back surface plate made of glass cannot satisfy laws and regulations in terms of head protection in collision with a pedestrian. Further, underneath the bonnet hood, an engine is disposed and some components become hot, and thus, when the back surface plate is made of a polycarbonate resin, it is concerning that the rigidity at high temperatures decreases. A structure using a metal plate for the back surface plate can address the aforementioned two issues, but adoption of a metal plate for the back surface plate increases the manufacturing cost. Use of a metal mesh as in the aforementioned conventional technique for the back surface plate could reduce the manufacturing cost, but a small wire diameter does not secure the rigidity, and thus, when mounted on a bonnet hood, it is concerning that the rigidity at high temperatures decreases, as described above. Meanwhile, an increased wire diameter for raising the rigidity could fail to perform three-dimensional shaping.

The present disclosure has been made in view of the foregoing and provides a solar cell module with a high rigidity capable of reducing the manufacturing cost.

To solve the foregoing, a solar cell module according to the present disclosure includes a solar cell unit including at least one solar cell, and a front surface plate and a back surface plate that are disposed, via a sealing material, on a light-receiving surface side and an opposite side of the light-receiving surface side of the solar cell unit, in which a woven metal plate is provided on the back surface plate, the woven metal plate being formed by weaving metal strips having a predetermined strip width.

According to the present disclosure, with a woven metal plate provided, as a structure, on a back surface plate, it is possible to provide a solar cell module with a high rigidity capable of reducing the manufacturing cost.

### BRIEF DESCRIPTION OF THE DRAWINGS

FIG. 1 is an enlarged cross-sectional view schematically showing the configuration of a solar cell module according to the present embodiment;

FIG. 2 is a plan view schematically showing the configuration of a woven metal plate of the solar cell module according to the present embodiment (a cross-sectional view schematically showing a cross-section cut along line A-A of FIG. 1);

FIG. 3 is a plan view schematically showing the configuration of the woven metal plate of the solar cell module according to a modification 1 (a cross-sectional view schematically showing the cross-section cut along line A-A of FIG. 1); and

FIG. 4 is an enlarged cross-sectional view schematically showing the configuration of the solar cell module according to a modification 2.

### DETAILED DESCRIPTION

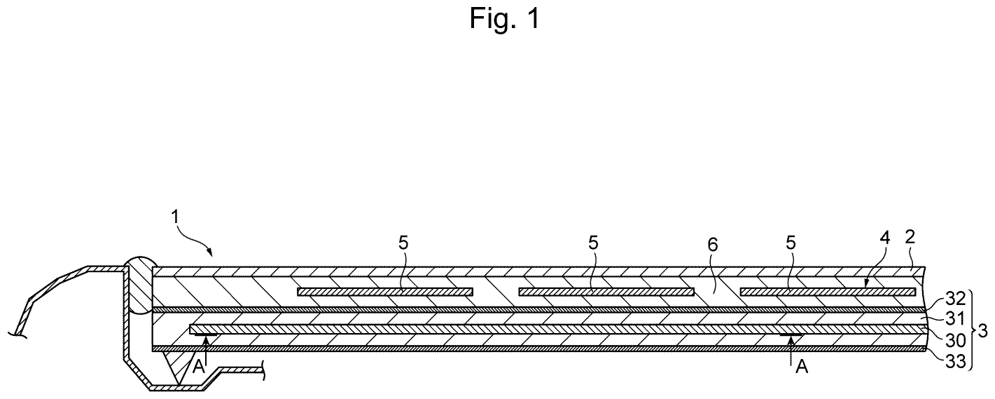

Hereinafter, an embodiment of the present disclosure will be described in detail with reference to the drawings from FIG. 1 to FIG. 4. Note that the embodiment shown below is one aspect of the present disclosure and does not limit the technical scope of the present disclosure.

In the embodiment shown below, an example of mounting a solar cell module 1 according to the present embodiment on a bonnet hood of a vehicle will be described. The solar cell module 1 has a curved plate-like shape. Therefore, it can be mounted on the bonnet hood in accordance with the shape of the bonnet hood of the vehicle similarly curved.

The solar cell module 1 has a front surface plate 2 (FIG. 1) formed of a translucent plate-like member on an uppermost layer of the bonnet hood. When the solar cell module 1 is irradiated with light such as sunlight, the irradiated light permeates the front surface plate 2 and then reaches the inside of the solar cell module 1. In this manner, an electromotive force is generated between the positive electrode and the negative electrode of the solar cell module 1, so that the generated electric power can be supplied to a vehicle or the like.

Note that the solar cell module 1 is thin and lightweight. Taking advantage of such properties, the solar cell module 1 can be mounted on not only the aforementioned bonnet hood of a vehicle but also various objects, including exterior panels such as roofs, fenders, doors, and rear trunks, and exterior panels or external walls of buildings other than vehicles.

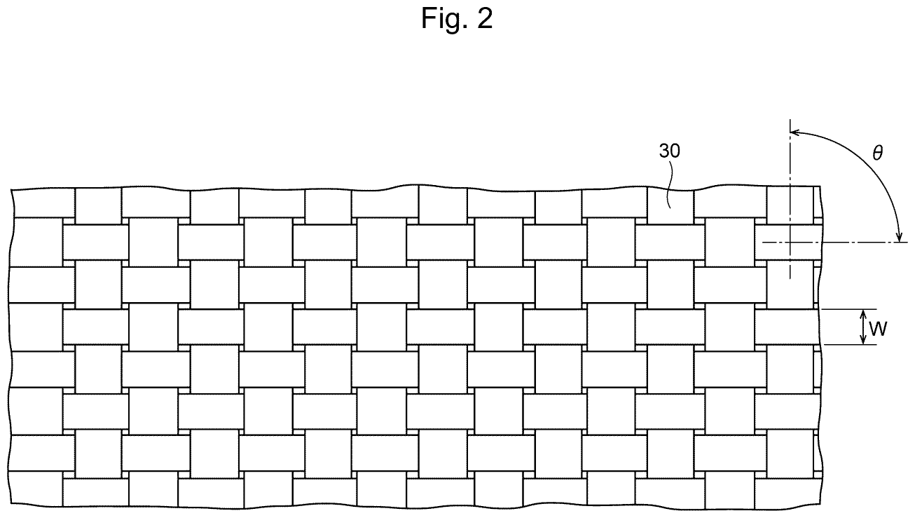

FIG. 1 is an enlarged cross-sectional view schematically showing the configuration of the solar cell module 1 according to the present embodiment. FIG. 2 is a plan view schematically showing the configuration of the woven metal plate of the solar cell module according to the present embodiment, that is, a cross-sectional view schematically showing the cross-section cut along line A-A of FIG. 1. Note that the solar cell module 1 is for on-vehicle use and is curved in accordance with the shape of the bonnet hood of the vehicle, but the cross-sectional view shows it in a flat plate shape, for a matter of convenience for explanation. The solar cell module 1 includes the front surface plate 2, a back surface plate 3, a solar cell unit 4 disposed between the front surface plate 2 and the back surface plate 3, a sealing material 6 that seals the solar cell unit 4, and the like. In other words, the solar cell module 1 has the front surface plate 2 and the back surface plate 3 that are disposed via the sealing material 6 on the light-receiving surface side and the opposite side (non-light-receiving surface side) of the light-receiving surface side of the solar cell unit 4.

The solar cell unit 4 has a plurality of solar cells 5 in a substantially rectangular shape, the plurality of solar cells 5 being slightly spaced apart from one another in plan view and arranged in a matrix. Each solar cell 5 has a power-generating device, electrodes, and the like, and is curved in accordance with the curved shape of the solar cell module 1.

As described above, the irradiated light permeates the front surface plate 2 and then reaches the inside of the solar cell module 1. This irradiated light reaches the power-generating devices (solar cells 5) to be absorbed, so that the irradiated light energy can be converted into an electrical energy. Note that the power-generating devices (solar cells 5) are electrically connected by means of an interconnector (not shown), and current flows through the entire solar cell unit 4 via the interconnector.

Note that the configuration of the solar cell unit, which is a power generating portion of the solar cell module 1, is not limited to the illustrated configuration. For example, in the present embodiment, the structure in which a single solar cell unit constitutes the power generating portion is illustrated, but a tandem structure in which first and second solar cell units are disposed vertically may also be applied. Further, the solar cells constituting the solar cell unit are not particularly limited, and any conventionally known solar cells can be used.

The present embodiment is characterized by the structure of the back surface plate 3 of the solar cell module 1, in which a structure with a high rigidity capable of reducing the manufacturing cost is provided on the back surface plate 3 of the solar cell module 1.

The typical manufacturing of the solar cell module 1 includes a lay-up process in which members are stacked, followed by a lamination process in which vacuum degassing and thermal pressing of the members are performed using a vacuum lamination device (also referred to as a laminator). Further, such manufacturing is widely adopted for products in a flat plate shape for residential and industrial use, where effective large-scale production and automated lines realize cost reduction.

Meanwhile, products for automobiles have a three-dimensional shape, for which the aforementioned solar cell manufacturing device for residential and industrial use cannot be repurposed, thus increasing manual operation and manufacturing cost.

Moreover, the lamination process for three-dimensional products also has a problem in that cell cracks are more likely to occur, which leads to a higher fraction defective and higher cost in terms of the manufacturing yield.

Therefore, lamination in a flat plate shape enables manufacturing of high-quality products at low cost.

Based on the above, the present embodiment proposes a structure of the solar cell module 1 (back surface plate 3 thereof) that can be thermally bent (shaped) into a three-dimensional shape after lamination in a flat plate shape.

Specifically, the back surface plate 3 includes a woven metal plate 30, a sealing material 31 that seals the woven metal plate 30, and the like. In other words, the back surface plate 3 is configured as a stacked member where the woven metal plate 30 provided as a structure is sandwiched by the sealing material 31. Further, the back surface plate 3 includes a plate-shaped insulating layer 32 on the solar cell unit 4 side (upper side) of the sealing material 31, in other words, between the woven metal plate 30 and the solar cell unit 4, and a plate-shaped resin layer 33 on the opposite side (lower side) of the solar cell unit 4 side in the sealing material 31. The back surface plate 3 (which the sealing material 31constitutes) is joined to the sealing material 6 on the upper side via the insulating layer 32. That is, in the present embodiment, the back surface plate 3 is provided with the woven metal plate 30 as a structure and is configured such that the plate-shaped insulating layer 32 and resin layer 33 are joined via the sealing material 31 on the solar cell unit 4 side (sealing material 6 side) and the opposite side of the solar cell unit 4 side (sealing material 6 side) of the woven metal plate 30.

The woven metal plate 30 is produced by weaving metal strips (metal plates) having a predetermined strip width W so as to cross with one another at a predetermined crossing angle θ (approximately 90° in FIG. 2), as shown in FIG. 2. The woven metal plate 30 is three-dimensionally curved in accordance with the curved shape of the solar cell module 1.

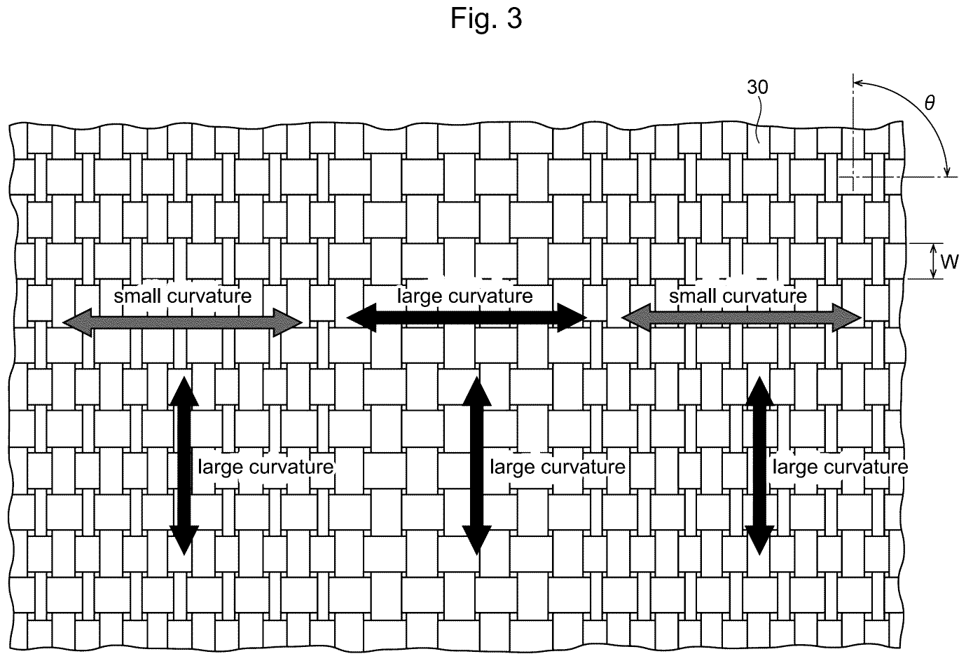

For example, when the solar cell module 1 is applied to the bonnet hood of a vehicle, the curvature of a design surface of the bonnet hood is determined by the vehicle design, and the strip width W of the strips constituting the woven metal plate 30 is set in accordance with the curvature of the design surface of the bonnet hood. Therefore, the strip width W of the strips constituting the woven metal plate 30 may be changed in accordance with the curvature of the design surface of the mounting site, as shown in FIG. 3, for example. For example, in sites where the curvature is small, the strip width W of the strips may be reduced (narrowed), and in sites where the curvature is large, the strip width W of the strips may be increased (widened). Similarly, the crossing angle θ of the strips constituting the woven metal plate 30 may be changed in accordance with the curvature of the design surface of the mounting site.

Hereinafter, some examples of the material or raw material and thickness of each member constituting the stacked structure of the solar cell module 1 of the present embodiment are illustrated in order from the sunlight incident side. However, it is obvious that the material or raw material and thickness of each member are not limited to the those listed below.
First layer: front surface plate 2
   Material: PC (polycarbonate) resin, acrylic resin, ETFE (ethylene-tetrafluoroethylene copolymer) film, etc. (PC resin in some embodiments)
   Thickness: 0.1-2 mm (1 mm in some embodiments)
Second layer: Sealing material 6 (sealing material sheet of upper side portion of solar cell 5)
   Material: EVA (ethylene-vinyl acetate copolymer), polyolefin, ionomer, PVB (polyvinyl butyral), etc. (polyolefin in some embodiments)
   Thickness: 0.4-1 mm (0.5 mm in some embodiments)
Third layer: Solar cell 5
   Raw material: Silicon (Si) cell, perovskite device, etc. (Si cell in some embodiments)
   Thickness: 0.1-0.2 mm (0.18 mm in some embodiments)
Fourth layer: Sealing material 6 (sealing material sheet of lower side portion of solar cell 5)
   Material: EVA, polyolefin, ionomer, PVB, etc. (polyolefin in some embodiments)
   Thickness: 0.4-1 mm (0.5 mm in some embodiments)
Fifth layer: Insulating layer 32
   Material: PC resin, acrylic resin, film such as ETFE, PET (polyethylene terephthalate) resin (PET resin in some embodiments)
   Thickness: 0.1-2 mm (0.5 mm in some embodiments)
Sixth layer: Sealing material 31 (sealing material sheet of upper side portion of woven metal plate 30)
   Material: EVA, polyolefin, ionomer, PVB, etc. (ionomer in some embodiments)
   Thickness: 0.1-2 mm (0.5 mm in some embodiments)
Seventh layer: Woven metal plate 30
   Raw material: steel plate, aluminum plate, titanium plate, etc. (steel plate, aluminum plate in some embodiments)
   Thickness: 0.1-1 mm (0.2 mm in some embodiments)
Eighth layer: Sealing material 31 (sealing material sheet of lower side portion of woven metal plate 30)
   Material: EVA, polyolefin, ionomer, PVB, etc. (ionomer in some embodiments)
   Thickness: 0.1-2 mm (0.5 mm in some embodiments)
Ninth layer: Resin layer 33
   Material: PC resin, acrylic resin, film such as ETFE, PET resin (PET resin in some embodiments)
   Thickness: 0.1-2 mm (0.2 mm in some embodiments)

The aforementioned members are laid up, and the solar cell module 1 is produced in a flat state using a vacuum lamination device (laminator). At this time, commonly adopted manufacturing devices for glass modules can be repurposed. After producing the solar cell module 1 in a flat state, the solar cell module 1 is shaped (thermally bent) into a bonnet shape using a three-dimensional mold. At this time, the strips constituting the woven metal plate 30 provided as a structure on the back surface plate 3 are shaped (thermally bent) while being slightly displaced from one another, so that the three-dimensionally curved solar cell module 1 can be produced.

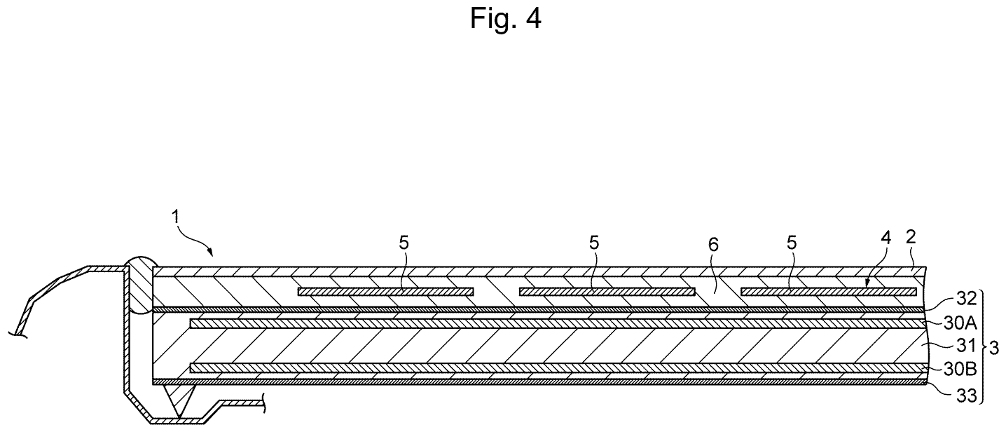

Note that in the aforementioned embodiment, the solar cell module 1 was produced using only one woven metal plate 30, but as shown in FIG. 4, by arranging the woven metal plate in two layers in the up-down direction (upper side woven metal plate 30A, lower side woven metal plate 30B) and using a hard ionomer resin or PVB resin with a Young's modulus of about 200 MPa for the intermediate sealing material 31, the shear deformation at the time of deformation due to module bending is suppressed, thereby achieving a commonly known honeycomb structure. This can reduce the weight while increasing the bending rigidity.

As some embodiments of the form shown in FIG. 4, the upper side woven metal plate 30A and the lower side woven metal plate 30B are formed of an aluminum plate with a thickness of about 0.1-0.5 mm, and the thickness of the intermediate sealing material 31 may be about 1-2 mm.

In summary, in the solar cell module 1 according to the present embodiment, the back surface plate 3 is provided with the woven metal plate 30 as a structure and is a stacked member in which the woven metal plate 30 is sandwiched by the sealing material 31.

In a process (1), a stacked structure is produced in a flat state using a vacuum lamination device (laminator), and thereafter, in a process (2), the stacked structure is shaped into a bonnet hood design using a three-dimensional mold.

In some embodiments, for use in a bonnet hood, the stacked structure has a bending rigidity substantially equal to t0.7 of an iron plate.

Further, the woven metal plate is structured such that the strip width W of the metal plate is narrowed for small curvatures and widened for large curvatures, in accordance with the three-dimensional curvature of the bonnet hood.

Although the plate is of metal, the metal plate is formed in a woven form, so that the structure that can be three-dimensionally shaped is realized. Thus, three-dimensional processing by thermal bending is possible after the lamination process in a flat state.

Further, since the aforementioned process (1) can realize the production of the solar cell module in a flat state (not three-dimensional), widely adopted manufacturing devices can be used. Additionally, only one mold needs to be prepared for the aforementioned process (2). This can reduce the manufacturing cost.

Furthermore, although the outer panel of a vehicle employs a steel plate, it is possible to reduce damage to a head at the time of collision between human and vehicle, by having the equivalent bending rigidity.

Moreover, for example, the curvature of the bonnet hood varies in size depending on the vehicle design, but the aforementioned woven structure can reduce the stress on the power-generating devices of the stacked solar cells.

The reason is that, for example, in a case of a large strip width with a small curvature, the bending portions of the strips become pointed, generating a load on the solar cell. This implies that there is an optimal strip width that suits the curvature of the design. Meanwhile, a reduced strip width can decrease the load on the solar cell, but when the strip width is small, the number of strips to be weaved increases, which is disadvantage in terms of the manufacturing cost. Therefore, an optimal strip width should be present that satisfies a desire for increasing the strip width (for cost reduction) as much as possible while reducing the strip width (for reducing the load on the cell) for a small curvature due to the design.

As described above, the solar cell module 1 according to the present embodiment includes the solar cell unit 4 including at least one solar cell 5, and the front surface plate 2 (translucent) and the back surface plate 3 that are disposed via the sealing material 6 on the light-receiving surface side and the opposite side (non-light-receiving surface side) of the light-receiving surface side of the solar cell unit 4, and the back surface plate 3 is provided with the woven metal plate 30 formed by weaving metal strips having the predetermined strip width W.

The back surface plate 3 is configured such that the insulating layer 32 and the resin layer 33 are joined via the sealing material 31 on the solar cell unit 4 side and the opposite side of the solar cell unit 4 side of the woven metal plate 30. The insulating layer 32 and the resin layer 33 may be formed of the same resin material.

The strip width W or the crossing angle θ of the strips is set (changed) based on the curvature of the mounting site of the solar cell module 1.

The solar cell module 1 has a curved shape.

The solar cell module 1 is mounted on a vehicle (for example, a bonnet hood, etc.).

According to the present embodiment, with the woven metal plate 30 provided, as a structure, on the back surface plate 3, it is possible to provide the solar cell module 1 with a high rigidity capable of reducing the manufacturing cost.

Note that the present disclosure is not limited to the aforementioned embodiment and can be appropriately modified and changed within the scope without departing from the purpose of the present disclosure.

### DESCRIPTION OF SYMBOLS

1 Solar cell module
2 Front surface plate
3 Back surface plate
30 Woven metal plate
31 Sealing material
32 Insulating layer
33 Resin layer
4 Solar cell unit
5 Solar cell
6 Sealing material
W Strip width
θ Crossing angle

What is claimed is:

1. A solar cell module comprising:
a solar cell unit including at least one solar cell; and
a front surface plate and a back surface plate that are disposed, via a sealing material, on a light-receiving surface side and an opposite side of the light-receiving surface side of the solar cell unit,
wherein a woven metal plate is provided on the back surface plate, the woven metal plate being formed by weaving metal strips having a predetermined strip width.

2. The solar cell module according to claim 1, wherein the back surface plate is configured such that an insulating layer and a resin layer are joined via a sealing material on a side of the solar cell unit and an opposite side of the side of the solar cell unit of the woven metal plate.

3. The solar cell module according to claim 1, wherein the strip width or a crossing angle of the strips is set based on a curvature of a mounting site of the solar cell module.

4. The solar cell module according to claim 1, wherein the solar cell module has a curved shape.

5. The solar cell module according to claim 1, wherein the solar cell module is mounted on a vehicle.
